(19) United States
(12) Patent Application Publication
(10) Pub. No.: US 2005/0095854 A1
(43) Pub. Date: May 5, 2005

(54) Methods for depositing high yield and low defect density conductive films in damascene structures

(76) Inventors: Cyprian E. Uzoh, San Jose, CA (US); Bulent M. Basol, Manhattan Beach, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/698,878

(22) Filed: Oct. 31, 2003

(51) Int. Cl. H01L 21/44

(52) U.S. Cl. 438/678

(57) ABSTRACT

A process of electrodepositing a substantially flat conductive layer on a workpiece surface is provided. In the process, various transition current densities are determined experimentally by evaluating the effects of the plating current density on gap fill profile in the smallest cavities with the largest tendency to over-plate on the substrate. After determining the transition currents on experimental wafers or dies, an electrochemical plating process is performed to apply selected transition current densities as process current densities to form a substantially flat profile over the smallest cavities.

### FIELD

The present invention relates to manufacture of semiconductor integrated circuits and, more particularly to a method for planar deposition of conductive layers.

### BACKGROUND

Conventional semiconductor devices generally include a semiconductor substrate, usually a silicon substrate, and a plurality of sequentially formed dielectric layers such as silicon dioxide and conductive paths or interconnects made of conductive materials. Interconnects are usually formed by filling a conductive material in trenches etched into the dielectric layers. In an integrated circuit, multiple levels of interconnect networks laterally extend with respect to the substrate surface. Interconnects formed in different layers can be electrically connected using vias or contacts.

The filling of a conductive material into features such as vias, trenches, pads or contacts, can be carried out by electrodeposition. In electrodeposition or electroplating method, a conductive material, such as copper is deposited over the substrate surface including into such features. Then, a material removal technique is employed to planarize and remove the excess metal from the top surface, leaving conductors only in the features or cavities. The standard material removal technique that is most commonly used for this purpose is chemical mechanical polishing (CMP). Chemical etching and electropolishing, which is also referred to as electroetching or electrochemical etching, are also attractive process options that are being evaluated for this application. Copper is the material of choice, at this time, for interconnect applications because of its low resistivity and good electromigration properties. During the copper electrodeposition process, specially formulated plating solutions or electrolytes are used. These electrolytes typically contain water, acid (such as sulfuric acid), ionic species of copper, chloride ions and certain additives which affect the properties and the plating behavior of the deposited material. Typical electroplating baths contain at least two of the three or more types of commercially available additives such as accelerators, suppressors and levelers. It should be noted that these additives are sometimes called different names. For example, the accelerator may be referred to as a brightener and the suppressor as a carrier in the literature. Functions of these additives in the electrolyte and the role of the chloride ion are widely known in the field (see for example, Z. W. Sun and G. Dixit, “Optimized bath control for void-free copper deposition”, Solid State Technology, November 2001, page. 97).

Depositing metals such as copper and its alloys into damascene or multiple damascene substrates needs to overcome many challenges. One of these challenges is the production of void-free and seam-free metal deposition within damascene cavities of varying dimensions, aspect ratios, and pattern densities. One other challenge is to minimize the variation in overburden range within any given die on the substrate, but also across the substrate; for example between the wafer center to wafer edge.

The first challenge may be resolved by diligent selection of plating electrolyte type and optimization of plating additives. However, the super filling phenomena which is required to produce void-free and seam-free metal deposition in submicron size cavities or features may at the same time create excessive non-uniformity within a given die of the wafer. This non-uniformity is often in the form of over-plating over the high pattern density regions with sub-micron size features, compared to the lower pattern density neighbors or field regions. High pattern density or high feature density regions are the regions of the wafer that include a plurality of features, often vias and narrow width trenches, and over plating over such regions causes bumps or protrusions of the plated material. Also, such over plating can occur over isolated submicron features.

FIG. 1 illustrates a substrate, such as an exemplary portion of a dielectric surface layer 10 of a semiconductor wafer 12. The dielectric layer 10 is formed into a damascene structure having exemplary features or cavities such as small features 14, medium features 16 and large features 18. Features 14, 16 and 18 may be vias or trenches. The features and surface 19 or field of the dielectric layer 12 are coated with a suitable barrier layer 20 and a copper seed layer (not shown), before the copper electroplating step. In this example, small features 14 form a high feature density region 22 and medium features form an intermediate feature density region 24. For device wiring process, it is typical to substantially electrodeposit more than enough copper to cover the large features, such as large trenches and pads, etc., as exemplified by the feature 18 in FIG. 1. Typically, the thickness of the metal coating may range between 1.2 to 1.8 times the depths of the large features for a good CMP planarization process, one of the subsequent step that follows the plating process. During plating, the small features 14 are the first to be filled on account of the super-filling phenomenon, while the larger features 16 and 18 are substantially under-filled as exemplified in the profile evolution of the gap fill process of the wafer 12 in FIGS. 2 to 4.

FIG. 2 shows an initial stage during a plating process where a copper film 26 fills the small features 14 and partially fills the medium features 16. The copper film 26 conformally coats the large features 18 at this stage. The curvature of film profile over the just-filled small features is shown concave, however, if excessive accelerator or non-optimal gap filling conditions are used, the curvature may be convex as shown in FIG. 3. As shown in FIG. 3 copper film above the each small feature is protruding. During the subsequent copper deposition to fill the medium and the large cavities, the coalescence of the various nodular growth fronts and planar growth fronts, produces an uneven copper overburden. The thickness of the overburden copper on the surface 19 of the dielectric layer depends on the width and density of the features beneath.

FIG. 4 shows formation of an overburden when the prior art deposition process is continued after either forming the structure in FIG. 2 or FIG. 3. Once the deposition is complete and the final overburden is formed on a predetermined area or a die area, the copper film thickness (h₁) over the dense small features is larger than the film thickness (h₂) over the medium features which in turn, is larger than the film thickness (h₃) adjacent the large features. Within a given die, the overburden range which is the difference between h₁ and h₃, may be as high as 400 nm or even larger.

Conventionally, overburden copper on the wafer is removed and planarized using CMP or electrochemical mechanical polishing (ECMP). In such processes, the metal removal rate ad the planarization efficiency depend on the process solution formulation, polishing pressure, and the relative velocity between the wafer surface and the polishing pad, amongst other process variables. In general, although the removal rate varies between the center and the edge of the wafer, it tends to be substantially the same across small distances, such as across a given die or a predetermined small area on the wafer. Thus, since the overburden thickness variations depicted in FIG. 4 are within the same die, the time required to remove the thickness h₁ by the CMP process is expected to be longer than the time needed to remove the thickness h₃. In fact, in a typical polishing process the additional time required to clear the extra copper thickness over the small and dense features to achieve electrical isolation between the features of interest is the key limiting step or parameter. For example, after reducing and then eliminating the copper thickness h₃, over polishing is carried out to remove the layer with thickness (h₂-h₃) and then (h₁-h₂) over the medium density and high pattern density, respectively. This additional step is the over polishing. As can be appreciated one of the main consequence of this step is that the features with comparatively smaller pattern densities such as medium and large features are also over polished during the period when the additional copper over the smallest features is removed. This incidental over polishing induces severe dishing and erosion defects in features 16 and 18 on the wafer 12, as shown in FIG. 5. High dishing and erosion cause large variance in the values of the electrical circuits parameters, and may also cause shorts and reduce yield in subsequent metal levels.

One method to reduce the problem of dishing has been to initially incorporate thicker dielectric layers on the wafer surface. After the copper removal step, the unwanted dielectric film material is also removed during a barrier removal step or after the barrier removal step. This approach which results in dielectric loss is not always effective. In addition, it introduces additional costs, due to expensive consumables and lower process throughout.

Another method to reduce the large metal overburden resulting from over plating over dense and small features is the incorporation of leveling additives into the plating chemistry. The judicious use of leveling additives such as Enthone Viaform VFL™ leveler (from Enthone Co.) in plating bath can reduce overburden range from above 400 nm to about 200 nm in some very high pattern density and deep damascene structures. However, use of levelers at high concentration may dramatically reduce the plating process window. For example, at lower leveler concentrations, less than 1 ml/L, the reduction in overburden range is not very effective. At high concentrations, for example 3 ml/L or higher, although range reduction may be better, the process window for good gap fill is severely restricted, giving rise to seams in narrow single and dual damascene structures.

In another attempt to reduce over-plating over high pattern density sub-micron damascene features, U.S. Pat. No. 6,432,821 teaches super-fill plating to fill the smallest features, reverse plating to remove the adsorbed plating additives and their by-products from the substrate, a second super-fill plating to fill intermediate size features, a second reverse plating to remove adsorbed plating additives and their by-products from the substrate, and a bulk fill plating with high current density to fill large features. This patent also notes that the super-fill and reverse plating operations may be repeated more than twice prior to bulk filling in order to provide the desired surface morphology. One of the shortcomings of the above mentioned prior-art method, is that first reverse plating step which renders the substrate anodic is performed when the intermediate size and large features are only partially filled. Rendering the substrate anodic, therefore, results in the incorporation of large quantity of undesirable chloride species over the surface of the copper in all the partially filled features. The subsequent plating step, essentially produces a buried layer of impurity-rich copper film within the intermediate and large cavities. Multiple reversal sets during the deposition step incorporate multiple zones or layers of chloride rich copper film. In general, chloride impurities are undesirable in metallic films, not only do they retard film grain growth, they typically degrade interconnect reliability.

From the foregoing, there is a need in the device wiring steps, for an effective metal deposition process that significantly reduces the overburden range within die in the metal deposition process without the use of reverse plating process. Dramatic reduction in within die and within wafer range to values less than 50 nm would be very beneficial. Such a process would improve CMP thru-put and simplify CMP process by eliminating excessive over polishing times. The resulting low defects (dishing and erosion) yield very small variance in device electrical parameters, such as line and via resistances and very high open and short yields.

### BRIEF DESCRIPTION OF THE DRAWINGS

FIGS. 1-4 are schematically illustrations of a prior art electrochemical deposition process which results in a non planar copper overburden;

FIG. 5 is a schematic illustration of a prior art defective structure formed after chemical mechanical polishing of the copper overburden;

FIG. 6 is a schematic cross sectional illustration of a workpiece surface having a barrier layer;

FIGS. 7A-7C are schematic illustrations of a filling process to fill smallest features on the workpiece surface to determine a transition current density;

FIGS. 8A-8C are schematic illustrations of a filling process to fill smallest features on the workpiece surface to determine first transition current density;

FIGS. 9A-9C are schematic illustrations of a filling process to fill smallest features on the workpiece surface to determine second transition current density;

FIGS. 10A-10C are schematic illustrations of a filling process to fill smallest features on the workpiece surface to determine third transition current density;

FIGS. 11A-11C are schematic illustrations of a filling process to fill smallest features on the workpiece surface to determine fourth transition current density;

FIG. 12 is a schematic illustration of a flat copper film filling the high density features and on the workpiece;

FIGS. 13-18 are graphs showing various wave-forms depicting current density-time characteristics of the electrochemical plating process of the present invention;

FIG. 19 is schematic illustration of a planar copper overburden layer electroplated using the process of the present invention;

FIGS. 20-21 are schematic illustrations of various planarization levels of the copper overburden shown in FIG. 19; and

FIG. 22 is a schematic illustration of a patterned structure of the planarized copper overburden shown in FIGS. 20-21.

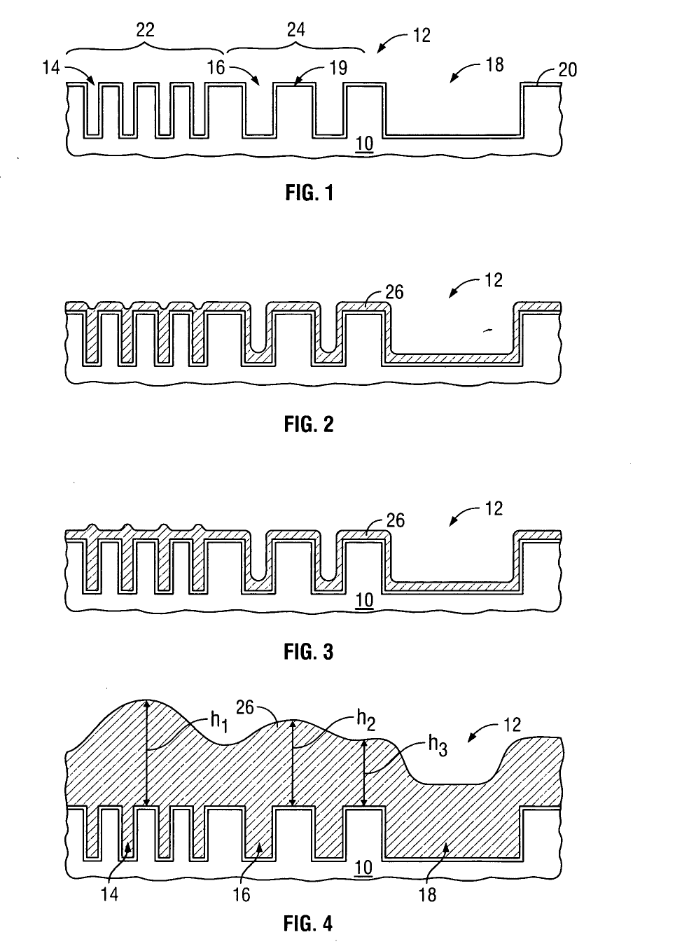

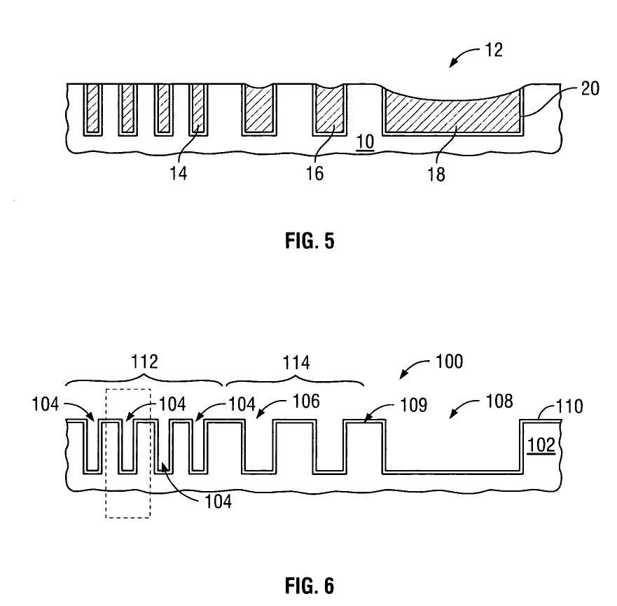

### SUMMARY

The present invention provides a process for reducing overburden or excess conductive material deposited on a workpiece using an electrochemical process. In the process. various transition current densities are determined experimentally by evaluating the effects of the plating current density on gap fill profile in the smallest cavities with the largest tendency to over-plate on the substrate. After determining the transition currents on experimental wafers or dies, an electrochemical plating process is performed to apply selected transition current densities as process current densities to form a substantially flat profile over the smallest cavities.

Accordingly, one aspect of the present invention provides a method of conductive material electrodeposition on a workpiece surface having a cavity to form a substantially flat conductive layer.

In one embodiment, the method includes the step of determining a first transition current density. The first transition current density is capable of filling the cavity with the conductive material and forms a substantially flat profile over the opening of the cavity. Next, a second transition current density is determined. The second transition current density is capable of filling the cavity with the conductive material and forms a substantially convex profile over the opening of the cavity. The second transition current density is larger than the first transition current density. A third transition current density is determined and the third transition current density is capable of filling the cavity with the conductive material and forms a substantially flat profile over the opening of the cavity. The third transition current density is larger than the second transition current density.

The method further includes the step of performing an electrodeposition process on a plurality of workpieces. Each electrodeposition process includes the steps of applying an initial process current density as the surface of the workpiece enters the process solution. The initial current density is lower than the first transitional current density. Next, a first process current density is applied to fill the cavity with the conductive material. The first process current density is substantially the same as the first transition current density. Further, a second process current density is applied to form a substantially flat conductive layer wherein the second process current density is substantially the same as the third transition current density.

In another aspect of the present invention, the first process current density is applied for a first predetermined time and the second process current density is applied for a second predetermined time.

In another aspect of the present invention, a third process current density is applied, the third process current density is applied before first process current density and after the initial process current density for a third predetermined time. The third process current density is higher than the second process current density, and the third predetermined time is shorter than the first and the second predetermined times.

In another aspect of the present invention, a third process current density is applied after the first current density and before the second process current density for a third predetermined time. The third process current density is higher than the second process current density, and the third predetermined time is shorter than the first and the second predetermined times.

In another aspect of the present invention, the first process current density is applied for a first predetermined time and a pulsed process current density is applied for a second predetermined time. The pulsed process current density varies between a third process current density and the first process current density and the third process current density is higher than the second process current density.

In another aspect of the present invention, the first process current density is initially applied for a first predetermined time and a first pulsed process current density is applied for a second predetermined time. The first pulsed process current density varies between the second process current density and the first process current density. Then, a second pulsed process current density is applied for a third predetermined time after the first pulsed current density. The second pulsed process current density varies between a third process current density and the second process current density and the third process current density is higher than the second process current density.

In another aspect of the present invention, the steps of applying the first process current density and the second process current density is repeated multiple times.

### DESCRIPTION OF THE INVENTION

The present invention provides a process for reducing overburden or excess conductive material deposited on a workpiece using an electrochemical process. The process of the present invention achieves this goal by reducing the thickness and by leveling the surface of the overburden layer, i.e., minimizing the overburden range problem which is mentioned above in the back ground section. The process improves the throughput of subsequent material removal processes, such as CMP by eliminating excessive time spent to remove large overburden range or localized thickness buildups on the workpiece. In one embodiment, based on the filling behavior of the high density features and the other less densely located features, the process of the present invention determines current densities to be used in various stages of the filling process or electrochemical plating process.

The process of the present invention initially determines a current density to electrochemically fill features or cavities of a group of high-density features using a predetermined process solution chemistry. After filling high-density features, the process continues using other predetermined current densities to complete filling of other features. Over all process of the present invention results in an overburden layer with no localized high bumps on the surface of the overburden. Term “high density features” refer to a plurality of features that are populated at certain sections of the wafer. Although not necessary, the high-density features of interest here have narrow width, often less than 1 micron. They may be vias or trenches or various combinations. As explained above, such high density locations are precursor for localized high bumps on the surface of the overburden due to the fact that the small features are filled before the larger ones and accelerating additive species are more active over the small features and thereby more local thickness build-up occurs on the high density small feature areas.

FIG. 6 shows an exemplary workpiece 100 such as a portion of a semiconductor wafer having a dielectric surface layer 102. The dielectric layer 102 is formed into a damascene structure having exemplary features or cavities such as small features 104, medium features 106 and large features 108. Features 104 and 106 may be vias or trenches or their various combinations. Features 108 may be trenches or pads. The features and surface 109 or field of the dielectric layer 102 are coated with a suitable barrier layer 110 and a copper seed layer (not shown), before the copper electroplating step. In this example, small features 104 form a high feature density region 112 and medium features 106 form an intermediate feature density region 114.

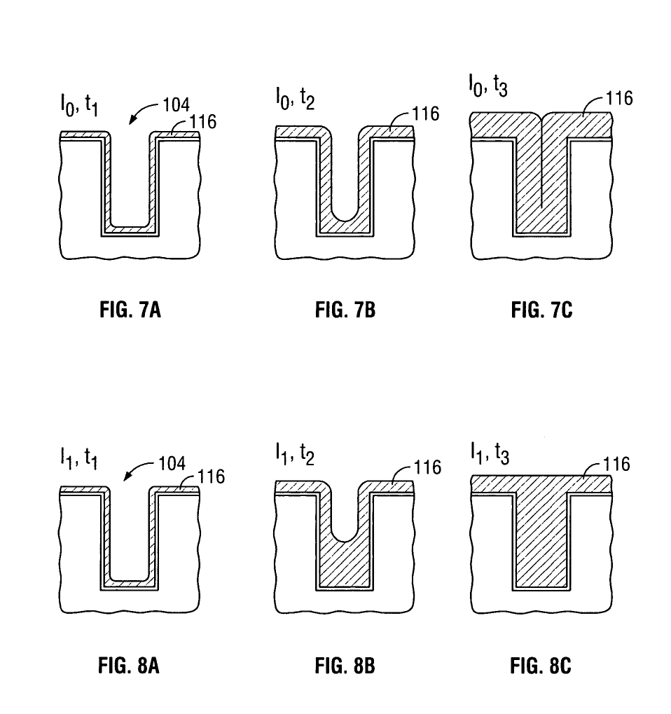

As shown in FIGS. 7A-11C, the process begins with observation of fill behavior of copper in small features 104 as the plating current density is increased. The process is preferably performed in a process solution having predetermined amount of additives, such as accelerators, suppressors and levelers. By starting with a small plating current density and changing it to higher values, and observing the filling of small features at each current density change, current density values, where “transitions” in the depositing copper layer profile occurs, are determined. These specific current densities are called transition current densities. The transition current densities are determined in an experimental step which may utilize cross-sectional Scanning Electron Micrographs or Focused Ion Beam (FIB) cross sections.

FIGS. 7A-11C show resulting time dependent evolution of copper layer profiles in a small feature 104 at various exemplary current densities such as I₀, I₁, I₂, I₃, I₄, . . . , Iₙ. These transition current densities are used to render the best filling conditions that prevent localized thickness non-uniformities on the overburden layer. During the process, an electroplating bath formulation containing known amounts of plating additives, such as accelerator, suppressor, and leveling agent are used. The various transition current densities I₀, I₁, I₂, I₃, I₄, . . . , Iₙ, may be determined experimentally by evaluating the effects of the plating current density on gap fill profile in the smallest cavities with the largest tendency to over-plate on the substrate. In accordance with the principles of the present invention, after determining the transition currents on experimental wafers or wafer pieces, an electrochemical plating process is performed to apply selected transition current densities as process current densities to plate batches of wafers having similar characteristics as the experimental wafers.

FIGS. 7A, 7B and 7C show first stage (t₁), second stage (t₂) and third stage (t₃) of the deposition process, respectively, using current density I₀. At I₀ current density, the copper film 116 starts forming conformally at time t₁ (FIG. 7A), and continues to be conformal at times t₂ and t₃ due to lack of bottom-up growth. This conformal growth causes the formation of a center seam in the copper film 116 at time t₃ as the deposition progresses. The copper profile formed in the feature 104 using current density I₀ cannot be used in semiconductor wire making due to seam defects and reliability concerns.

FIGS. 8A, 8B and 8C show first stage (t₁), second stage (t₂) and third stage (t₃) of the exemplary deposition process, respectively, using the current density I₁ which is a current density larger than the current density I₀. At the current density I₁, copper film 116 forms in a bottom-up fashion (faster growth from the bottom of the feature 104 than from side walls of the feature 104) as indicated by the profile of the copper film 116 taken at time t₂. In this region of the first transition current density, the gap fill is seamless and void-free. Furthermore, plating until time t₃ does not give rise to over-plating, or protrusion over the small features, when carefully controlled amount of plating charge is deposited on the device. At this current density, the accelerators are active, but their activity is not highly pronounced. The suppressor and presence of leveler to some extent moderate the activity of the accelerator. The resulting copper film profile is relatively flat or it has small dimples at time t₃. I₁ is the first transition current density which causes a transition in the resulting copper profile from seamed to flat and well filled.

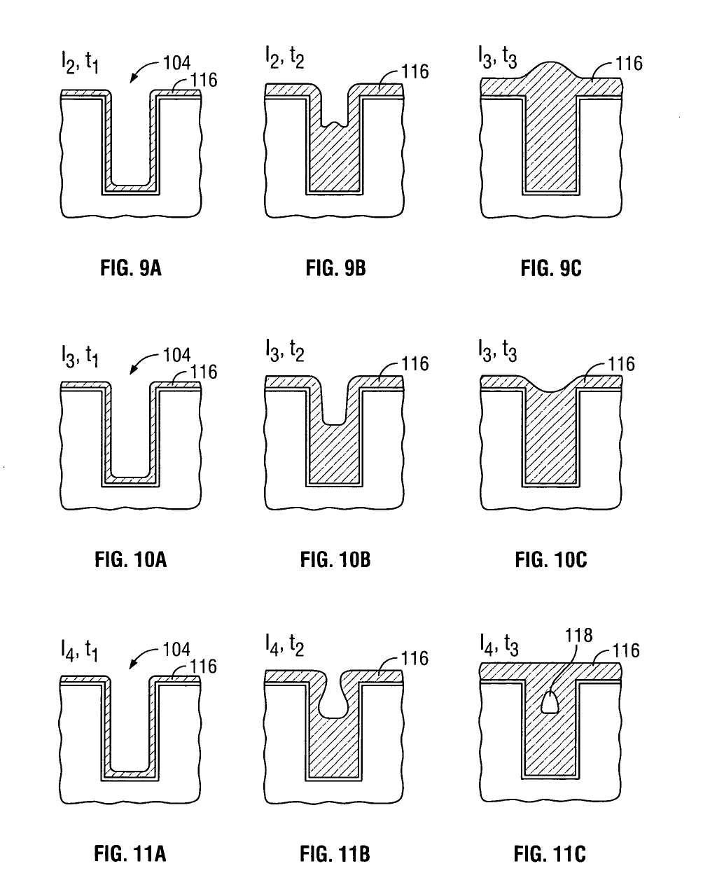

As the plating current density is further increased, the activity of the accelerator becomes more pronounced. This can be seen in FIGS. 9A, 9B and 9C which show first stage (t₁), second stage (t₂) and third stage (t₃) of the exemplary deposition process, respectively, using current density I₂. For example, using equivalent charge, the deposit profile after gap fill in the small features exhibits a pronounced over-plating (bump) at time t₃ over the small feature 104. It should be noted that the superposition of the overfilled regions during subsequent metal deposition steps gives rise to the large overburden variation depicted in FIG. 4. I₂ is the second transition current density, which causes a transition in the resulting copper profile from flat to bumped.

A further increase in current density beyond the second transition current density I₂ can be seen in FIGS. 10A, 10B and 10C which show first stage (t₁), second stage (t₂) and third stage (t₃) of the exemplary deposition process, respectively, using current density I₃ which induces a reversal in copper deposition evolution profile. At this new transition current density, I₃, gap fill proceeds in a bottom-up fashion as shown by the profile of copper film 116 at t₂. This is similar to the cases in FIGS. 8B and 9B. However, when gap fill is completed at time t₃, the profile of the deposit over the small feature 104 is either planar as in the case of above described process with I₁ current density or slightly concave. In the current density I₃, the activity of the leveling agent is becoming more pronounced and the growth of a bump is arrested. I₃ is the third transition current density that causes a transition in the resulting copper profile from bumped, back to flat.

Further increase in metal deposition rate, by increasing the current density during gap fill, produces the fourth transition current density, I₄. FIGS. 11A, 11B and 11C show first stage (t₁), second stage (t₂) and third stage (t₃) of the exemplary deposition process, respectively, using current density I₄. At this current density, the lateral growth rate of the copper film 116 adjacent the opening of the small feature 104 with respect to the dimension of the gap exceeds the growth rate of the copper film 116 from the bottom of the feature 104. This leads to premature closure of the entrance of the small feature, producing a top void 118 as illustrated in FIG. 11C. Therefore, the fourth transition current density I₄ causes a transition in the final copper profile from flat and well filled to voided profile. Voided copper cannot be used for interconnect fabrication.

Accordingly, as shown in FIGS. 7A-7C, copper deposition with the current density 10, gives rise to a deposit a profile which is conformal, as lateral growth rate and bottom growth rate are both about the same. At I₁, the growth rate of copper film 116 from the bottom exceeds the lateral growth rate, which FIGS. 8A-8B shows that bottom-up growth within the feature 104 is sufficiently pronounced to overcome moderating influences of the suppressor or leveler. This produces a flat profile over the small feature 104. In FIG. 9A-9C, the effect of accelerator is pronounced at current density I₂ causing a bump over the feature. With I₃ current density, the interaction of the electric field with the activity of the suppressor and leveler moderates the activity of the accelerator and arrests the growth of over plated regions as shown in FIGS. 10A-10C.

The present invention involves formulating a plating chemistry with or without a leveling additive, but preferably with a leveling agent. The wafer of interest is first coated with a suitable barrier and base or seed layer, and then is immersed into the electrolyte with a hot entry condition. Hot entry provides a small current density such as Iᵢ, which may be less than I₁, nominally between 0.5 and 5 mA/sq.cm, to wet the substrate and prevent seed layer loss or dissolution in the electrolyte. During the wetting step, the substrate may rotate between 2 to 10 rpm. The substrate may also translate in lateral direction with a velocity that may range between 1 to 50 mm/s. Hot entry may not have to be used if the seed layer is thick and its integrity is good.

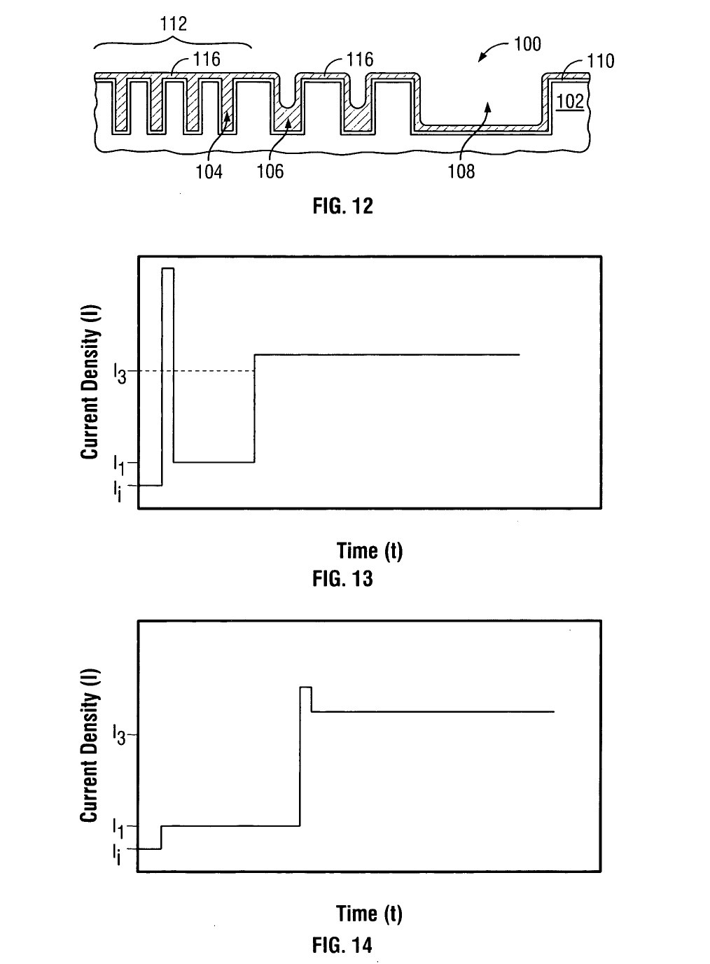

After the substrate-wetting step, the rotation of the wafer may be increased to between 50 to 150 rpm and the substrate may also be translated at higher speeds. During this step, the wafer is plated with an optimal plating charge, under fixed DC galvanostatic or potentiostatic or pulsed DC conditions, with current density at or beyond the first transition current density I₁ but below the second transition current density I₂. The optimal plating charge is selected to just fill the small features within the wafer, and to maintain a planar metal surface growth front, with near negligible overburden range or with very thin overburden. This plating charge, is just sufficient to fill the small features, while preventing the onset of bumps or nodular growth front over any of the small features on the substrate, as shown in FIG. 12. FIG. 12 shows copper film 116 coating the high density region 112 with a planar film.

It is preferable that the overburden over the field area adjacent to the small features be thinner or comparable to the seed layer thickness or at the most thinner than about three times the seed layer thickness. The careful selection of the plating current density and plating conditions during the filling of the small features is essential to preventing or minimizing the formation or initiation of bumps over the small features as was indicated in FIG. 3. For example, upon filling the small features in the substrate, a mild concave copper front growth profile is more desirable over the small cavities as shown in FIG. 2. After filling the small features as described above, the plating current density is increased to a value to or above the third transition current density (I₃) but preferably below the fourth transition current density (I₄) to complete the rest of the gap fill, to the appropriate overburden of interest, typically 1.2 to 2 times the depth of the features. As explained in association with FIGS. 7A-11 C, the third transition current density activates the suppressor and leveler and avoids formation of a bump over the small features. It should be noted that the second transition current density I₂ is avoided in this example.

FIGS. 13-18 show various wave-forms depicting current density-time characteristics of the electrochemical plating process of the present invention. At this process stage of the present invention, previously determined current density values (I₀, I₁, I₂, I₃, I₄ etc.) are used to conduct electroplating process on one more wafers having similar characteristics as the experimental wafers.

As shown in FIG. 13, in one embodiment of the process, after the initial hot entry with current density Iᵢ, the plating current density may be pulsed shortly to achieve negligible overburden range across the wafer. As shown with the wave form graph in FIG. 13, for example, the plating current density maybe increased momentarily to about 10 to 200% over the third transition current density I₃ for times between 0.2 to 10 seconds, but preferably between 0.5 to 8 seconds, after which the plating current density is then reduced to around or just above the first transition current density I₁ to fill the small features, with sufficient current. After filling the small features, the current density is increased to or just above the third transition current density (I₃) to complete the entire structure fill.

In another embodiment, as shown in FIG. 14, after filling the small features on the wafer, the current density may be increased to about 1.1 to 2 times the value of the third transition current density (I₃) momentarily for about 0.5 to 5 seconds before reducing the current density to just above the third transition current density (I₃) to completely fill the structure.

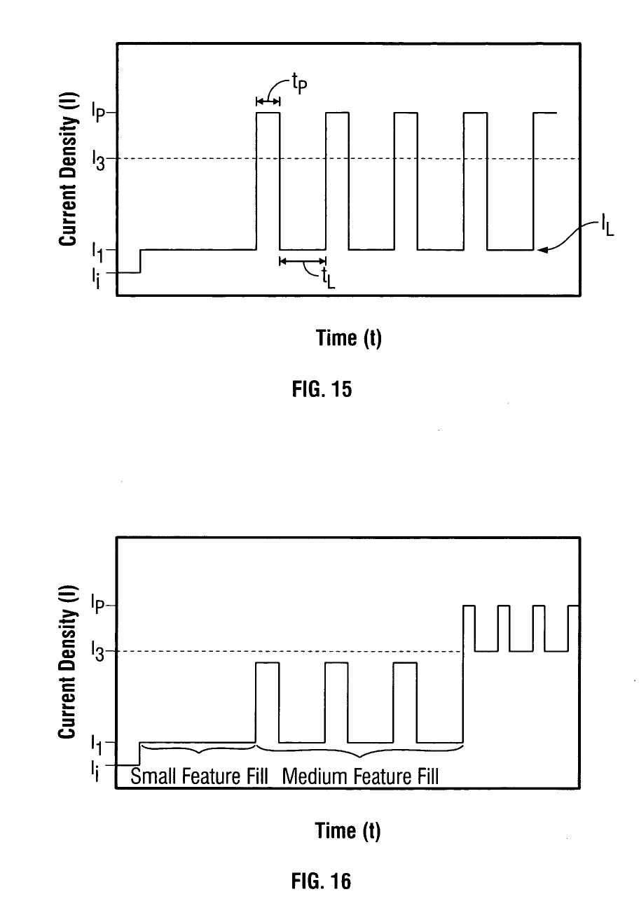

As shown in FIG. 15, in still another embodiment of this invention, to minimize, or eliminate overburden range within die or across wafer, after filling the small features with nominal plating current densities at or slightly beyond the first transition plating current density (I₁) but below the second transition current density (I₂). For example, the plating current density may be pulsed between a value at or higher than the third transition current density I₃ at the high end and around the first transition current density I₁ for the lower end. About 3 to 10 or more pulse cycles may be used to suppress the evolution of non-uniform overburden across the substrate. For example, after gap fill with the first transition current density I₁ for 40s, the current is ramped to third transition current density I₃ for about 1 to 4 sec, but preferably for 3 sec, then the current is decreased to I₁ the first transition current density for about 3 to 8s. This sequence of operation may be repeated for sufficient number of cycles such as 3 to 10 cycles or more to completely fill the large features. Then the rest of the plating process is completed with a current density of I₃ or higher.

In the pulsed waveform approach exemplified above, the pulse duration (tₚ) at the higher current density Iₚ, may be comparable to the pulse duration (t_{L}) at the lower current density I_{L}. Also, the peak pulse current Iₚ may be higher than the third transition current density I₃. In this instance, it may be preferable that the ratio of the pulse duration tₚ/t_{L}≦1. For example, for a peak current density Iₚ≧I₃, and for I_{L} close to the first transition current density I₁ the ratio of the pulse duration tₚ/t_{L}=⅜<1.

In yet another embodiment of this invention, as illustrated in FIG. 16, for difficult to fill features, especially those with undercut structures, the small features may be filled with a current density close to I₁, or by pulsing between two or more current densities, selected around the first transition current density I₁ and around the third transition current density I₃ to minimize overburden range within a die or a predetermined area on the wafer, the pulse duration ratio for the higher current density pulse to the lower current density pulse should be ≦1. The medium features may be filled with current densities pulsing between, for example, the first transition I₁ and third transition I₃ current densities, while minimizing overburden range within the device. After filling the medium features, the relative pulsing current densities may be increased to the third transition current density I₃ or higher. The new larger pulsing current density Iₚ is such that I₃<Iₚ<4I₃. The rest of the features may be filled by pulsing between I₃ and Iₚ as illustrated in FIG. 16 or between I₁ and Iₚ. The pulsing between high current density Iₚ and a much lower current density I₁ is very effective in suppressing over-plating or bump in damascene structures, especially widths between 500 nm to 20 microns.

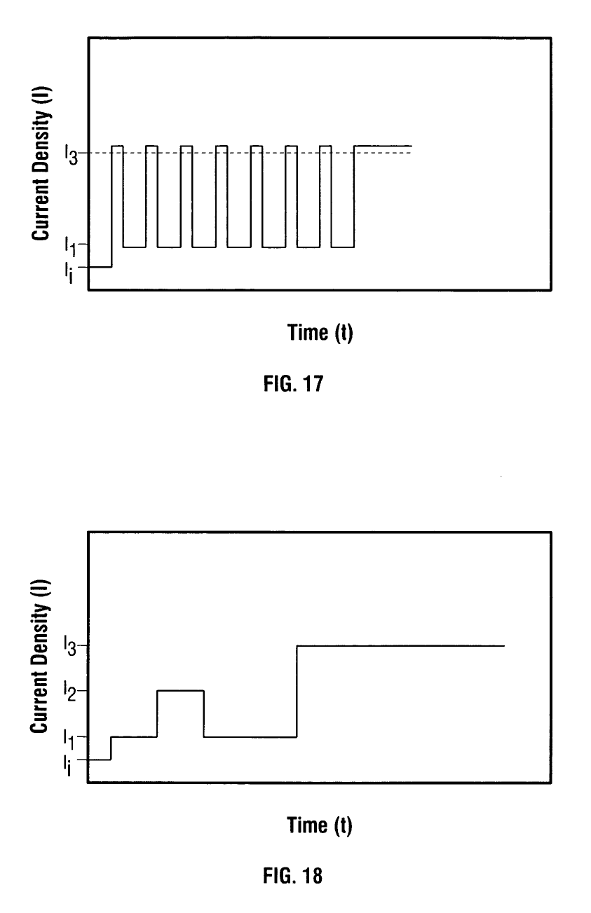

As shown in FIG. 17, in another embodiment, void-free gap fill may be completed after the initial wetting operations at current density Iᵢ, then the plating current density may be pulsed between the first transition current density I₁ and around the third transition current density I₃ for sufficient cycles to fill the small and medium features. This is followed by final fill at a current density close to I₃ or above I₃.

As shown in FIG. 18, in another embodiment after a brief partial gap fill at a current density I₁, the current density is brought to I₂ momentarily, next the current density is reduced to I₁ to fill the small features. After the filling, the current density is increased to I₃ to fill medium and large features.

In another embodiment of this invention, after filling the small features of interest with the adequate metal charge, and with very small overburden, the current density may be ramped to a higher current density I₃. The current density ramping profile between the initial filling current density and the intermediate or final current density may be linear or saw-tooth, or pulsed ramping.

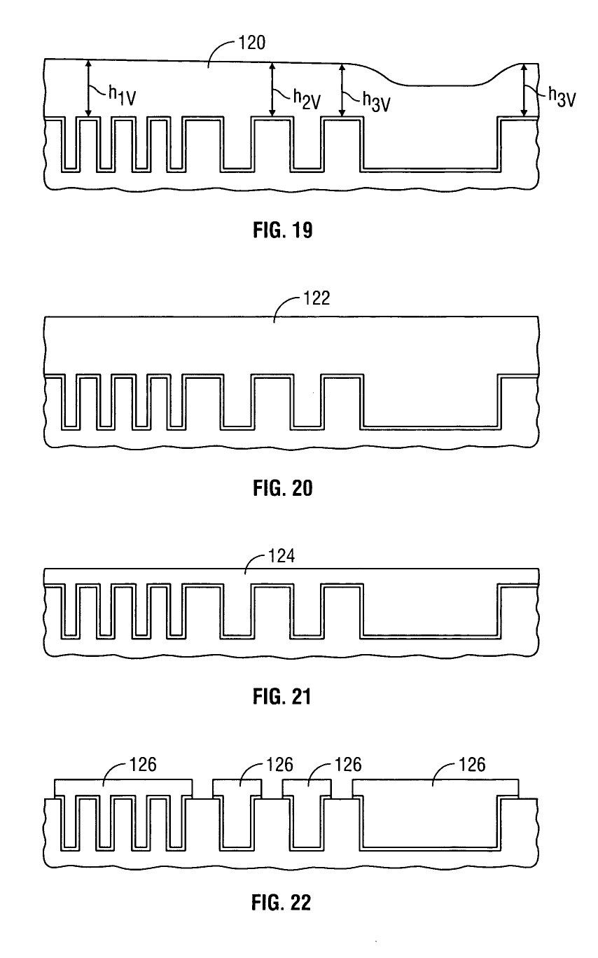

The copper film 120 or overburden plated with the process of the present invention is shown in FIG. 19. The thickness h_{2V} over intermediate size features, h_{1V} over the small features and the thickness over the field h_{3V} are about the same. The overburden range across the die (h_{1V}-h_{3V}) is typically less than 50 nm. Hence, the overburden range within a die or predetermined area on the wafer may be about the same or less than the precision of the device or equipment needed to measure the overburden range, such as a Dual Beam FIB/SEM System. This dramatic reduction in overburden range without the use of pulse reversal process is much smaller than the value of 150 to 500 nanometers (nm) which is typical for traditional plating practice of FIG. 4. Attempts have been made to obtain similar results by utilizing reverse pulse processes. However, reverse pulse processes employing sub-second pulses require special power sources. Further, reverse pulses may introduce defects and undesirable effects in crystal structure of the deposited film.

The CMP process for the plated metal of present invention with small to negligible within die overburden variation results in devices with very high yield in the immediate metal level of interest as well as in subsequent metal levels. Also, the standard deviation of the electrical devices within die and across the substrate is very small, because of the minimal over polishing times needed to remove the deposited metal across the substrate.

After the deposition of metal on the substrate with very small or negligible overburden variation as illustrated in FIG. 19, the substrate is preferably annealed at a suitable temperature, to stabilize the plated metal. After the annealing step, the excess copper overburden and the barrier layer may be removed by CMP methods, or by electrochemical mechanical planarization process or by optical-chemical mechanical planarization step or by electro- optical-chemical mechanical planarization methods or their various combinations. During planarization methods employing electric field, the plated metal may be removed in a suitable electrolyte in the presence of a pad material, rendering the substrate anodic with respect to a cathode and utilizing the various pulse combinations of this invention to planarize the plated metal or to remove the bulk of the metal layer.

In further aspect of this invention, as shown in FIG. 20, a planar copper overburden layer 122 may be plated over the substrate using ECMD or other methods which results in a uniform planar over burden, with negligible overburden variation within die and across the entire wafer or substrate. After planarizing the copper layer 120 shown in FIG. 19 or after obtaining the planar copper layer 122 in FIG. 20. The wafer with the either planar layer is preferably annealed at a suitable temperature, to stabilize the plated metal. The bulk of the planar metal may then be removed in a suitable process solution, rendering the substrate anodic with respect to a cathode and utilizing the various pulse combinations of this invention to remove the bulk of the planar metal, as shown in FIG. 21. The remaining thin planar film 124 may be removed by, for example, one step CMP process.

In another embodiment of this invention, as shown in FIG. 22, the planar thin film may be patterned by lithographic methods, the unwanted metal removed to define a patterned copper layer 126, which is a new wiring layer structure. Thus, the process of this invention, utilizing the negligible overburden range, and planar material removal steps, is used to create a new or partial wiring level over a single or dual damascene metal wiring level. Although the copper deposition is used as an example in this invention, the method of this invention may be applied to the deposition of other materials, such as nickel, cobalt, tungsten, palladium, gold and other noble metals such as platinum rhodium, etc. and there respective alloys and laminates on any substrates of interest. Also, the method of this invention, for example of pulsing between one or more intrinsic properties or process parameters such as temperature, pressure, flow rate, plasma density, substrate electrode bias etc. may be used in other fluid process, including vacuum processing to deposit or remove metals and insulators, while minimizing or eliminating overburden range variation across the substrate.

Although various preferred embodiments and the best mode have been described in detail above, those skilled in the art will readily appreciate that many modifications and combination of the exemplary embodiments are possible without materially departing from the novel teachings and advantages of this invention.

1. A method of conductive material electrodeposition on a workpiece surface having a cavity to form a substantially flat conductive layer, the method comprising:
determining a first transition current density that is capable of filling the cavity with the conductive material forming a substantially flat profile over the opening of the cavity;
determining a second transition current density that is capable of filling the cavity with the conductive material forming a substantially convex profile over the opening of the cavity, wherein the second transition current density is larger than the first transition current density;
determining a third transition current density that is capable of filling the cavity with the conductive material forming a substantially flat profile over the opening of the cavity, wherein the third transition current density is larger than the second transition current density;
performing an electrodeposition process on a plurality of workpieces, each electrodeposition process comprising the steps of:
applying an initial process current density as the workpiece surface enters the process solution, wherein the initial current density is lower than the first transitional current density;
applying a first process current density to fill the cavity with the conductive material, wherein the first process current density is substantially the same as the first transition current density; and
applying a second process current density to form a substantially flat conductive layer; wherein the second process current density is substantially the same as the third transition current density.

2. The method of claim 1, wherein the step of applying the first process current density is applied for a first predetermined time and the step of applying the second process current density is applied for a second predetermined time.

3. The method of claim 2, further comprising applying a third process current density before the first process current density and after the initial process current density for a third predetermined time, wherein the third process current density is higher than the second process current density, and the third predetermined time is shorter than the first and the second predetermined times.

4. The method of claim 2, further comprising applying a third process current density after the first current density and before the second process current density for a third predetermined time, wherein the third process current density is higher than the second process current density, and the third predetermined time is shorter than the first and the second predetermined times.

5. The method of claim 1, further comprising applying the first process current density for a first predetermined time and applying a pulsed process current density that varies between a third process current density and the first process current density for a second predetermined time, wherein the third process current density is higher than the second process current density.

6. The method of claim 1, further comprising applying the first process current density for a first predetermined time and applying a first pulsed process current density that varies between the second process current density and the first process current density for a second predetermined time.

7. The method of claim 9, further comprising applying a second pulsed process current density for a third predetermined time after the first pulsed process current density, wherein the second pulsed process current density varies between a third process current density and the second process current density, wherein the third process current density is higher than the second process current density.

8. The method of claim 1, further comprising repeating the steps of applying the first process current density and the second process current density multiple times.

9. A method of conductive material electrodeposition on a workpiece surface having a cavity to form a substantially flat conductive layer, the method comprising:
determining a first transition current density that is capable of filling the cavity with the conductive material forming a substantially flat profile over the opening of the cavity;
determining a second transition current density that is capable of filling the cavity with the conductive material forming a substantially convex profile over the opening of the cavity, wherein the second transition current density is larger than the first transition current density;
determining a third transition current density that is capable of filling the cavity with the conductive material forming a substantially flat profile over the opening of the cavity, wherein the third transition current density is larger than the second transition current density; and
performing an electrodeposition process on a plurality of workpieces by depositing the conductive material onto the surface of the workpieces using a variable current density including an initial process current density, a first process current density and a second process current density to form the flat conductive layer;
wherein the first process current density is substantially the same as the first transition current density, and the second process current density is substantially the same as the third transition current density.

10. The method of claim 9, wherein the first process current density is applied for a first predetermined time and second process current density is applied for a second predetermined time.

11. The method of claim 10, wherein the first predetermined time period is equal to the second predetermined time period.

12. The method of claim 10, wherein the first predetermined time period is longer than the second predetermined time period.

13. The method of claim 10, wherein the first predetermined time is shorter than the second predetermined time.
